(19) United States
(12) Patent Application Publication
(10) Pub. No.: US 2014/0002057 A1
(43) Pub. Date: Jan. 2, 2014

(54) WIRELESS INTELLIGENT SOCKET ASSEMBLY WITH ENHANCED COMMUNICATION PERFORMANCE

(71) Applicants: Roy Ting, New Taipei City (TW); Max Li, Dana Point, CA (US)

(72) Inventors: Roy Ting, New Taipei City (TW); Max Li, Dana Point, CA (US)

(21) Appl. No.: 13/902,972

(22) Filed: May 27, 2013

(30) Foreign Application Priority Data
Jun. 29, 2012 (TW) 101212681

(51) Int. Cl. G01R 21/00

(52) U.S. Cl. CPC G01R 21/00
USPC 324/96

(57) ABSTRACT

A wireless intelligent socket assembly has a wireless intelligent socket having a contact hole formed through one side thereof and electrically connected to a control circuit, a cover mounted on the top of the wireless intelligent socket and having an opening formed there through, a one connection wire and an extended antenna. One end of the connection wire is electrically connected to a corresponding contact hole, and the other end is electrically connected to an inner end of a corresponding through hole of the cover. One end of the extended antenna is electrically connected to an outer end of a corresponding through hole, and the other end extends to a location outside the wireless intelligent socket and not blocked by any foreign object. Accordingly, information detected by the control circuit can be transmitted out through the extended antenna to enhance communication performance of the wireless intelligent socket.

### BACKGROUND OF THE INVENTION

1. Field of the Invention

The present invention relates to a wireless intelligent socket assembly with enhanced communication performance and more particularly to a wireless intelligent socket assembly having an extended antenna mounted through a wireless intelligent socket and a cover of the assembly to enhance communication performance information transmitted or received by the wireless intelligent socket assembly.

2. Description of the Related Art

In view of the aggravating energy shortage problem, advocating for energy conservation and environmental protection has become a global consensus. According to research about ten percent of regular household electric power consumption is wasted by the standby power of electric appliances.

Luckily, newly developed intelligent chip modules can be mounted on home electric appliances to significantly lower the standby power of electric appliances plugged in a power source, and can be also designed in intelligent sockets for the purpose of detection of abnormal power consumed by electric appliances and digital management of household power sources, so as to save unnecessary energy wasted and achieve energy-conserving and power-saving effect. Besides, when power consumed by electric appliances is irregular, the power sources can be automatically cut off, rendering more flexibility and safety in terms of household power utilization.

Moreover, every conventional wireless intelligent socket assembly has a control circuit using an intelligent chip module to detect the power consumption of the conventional wireless intelligent socket assembly and wirelessly transmits information of the detected power consumption to a control terminal, such as a host server, for the control terminal to perform integrated control and management over the collected information of power consumption and automatically disconnect electric appliances from power sources to ensure safety protection when the electric appliances are overloaded or in a stand-by mode.

However, with reference to FIG. 1, a transceiving unit of the control circuit of a conventional wireless intelligent socket assembly is mounted inside the wireless intelligent socket assembly. Usually, a wall-mount wireless intelligent socket assembly is located behind electric appliances, storage cabinets or iron cabinets. As a result, the detected information transmitted from the control circuit of the conventional wireless intelligent socket assembly is interfered or blocked by the electric appliances or the preceding objects, and is unable to be effectively transmitted to the control terminal. Those communication barriers disallow the control terminal to completely receive all the detection signals transmitted from each wireless intelligent socket assembly, serious communication flaw therefore appears in the intelligent power control and management, and the conventional intelligent socket downgrades its function and efficacy. Just image the energy waste arising from the uncontrollable individual household electricity usage, let alone the astonishing accumulation of all the energy waste in a community, which surely impacts on the across-the-board fulfillment of metropolitan or nationwide power utilization control and management.

### SUMMARY OF THE INVENTION

In view of the foregoing problem, the objective of the present invention is to provide a wireless intelligent socket assembly. The wireless intelligent socket assembly has a wireless intelligent socket, a cover, at least one connection wire and at least one extended antenna.

The wireless intelligent socket has multiple sets of plug holes, a control circuit and at least one contact hole.

The multiple sets of plug holes are formed through a top of the wireless intelligent socket.

The control circuit is mounted inside the wireless intelligent socket to detect a consumed power of each set of plug holes and wirelessly transmit information of the consumed power.

The at least one contact hole is mounted through one side of the wireless intelligent socket and is electrically connected to the control circuit inside the wireless intelligent socket.

The cover is mounted on the top of the wireless intelligent socket and has an opening and at least one through hole.

The opening is formed through the cover with the multiple sets of plug holes exposed through the opening

The at least one through hole is formed through the cover. One end of each one of the at least one connection wire is electrically connected to a corresponding contact hole, and the other end is electrically connected to an inner end of a corresponding through hole of the cover.

One end of each one of the at least one extended antenna is electrically connected to an outer end of a corresponding through hole, and the other end is a free end adapted to extend to a location ahead of the wireless intelligent socket and not blocked by any foreign object.

Accordingly, information detected by the control circuit can be transmitted out through the extended antenna to enhance communication performance of the wireless intelligent socket.

### BRIEF DESCRIPTION OF THE DRAWINGS

FIG. 1 is a schematic view of an application using a conventional wireless intelligent socket assembly;

FIG. 2 is a partially exploded perspective view of a wireless intelligent socket assembly in accordance with the present invention;

FIG. 3 is a perspective view of the wireless intelligent socket assembly in FIG. 2;

FIG. 4 is an operational perspective view of the wireless intelligent socket assembly in FIG. 3;

FIG. 5a is a schematic view of an embodiment of a positioning element mounted on an end of an extended antenna of the wireless intelligent socket assembly in FIG. 3;

FIG. 5b is a schematic view of another embodiment of a positioning element mounted on an end of an extended antenna of the wireless intelligent socket assembly in FIG. 3; and

FIG. 6 is schematic top and side views of the wireless intelligent socket assembly in FIG. 3 having a winding mounted thereon.

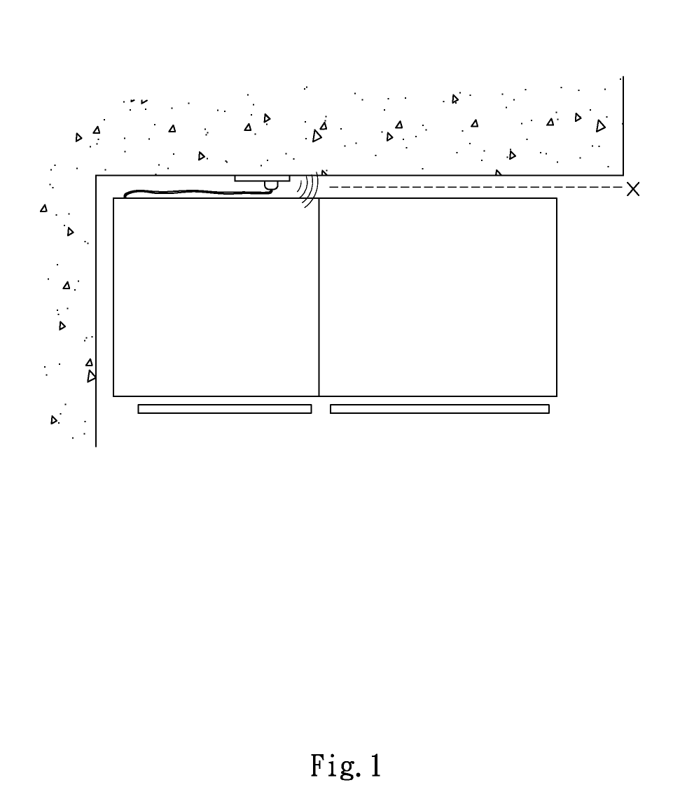

### DETAILED DESCRIPTION OF THE INVENTION

To facilitate examiner's easy and fast understanding of the features and advantages of the present invention and make the achieved effects more apparent, the following embodiments are used in conjunction with the accompanying drawings to elaborate on the features and advantages of the present invention instead of limiting the scope of the present invention from any point of view.

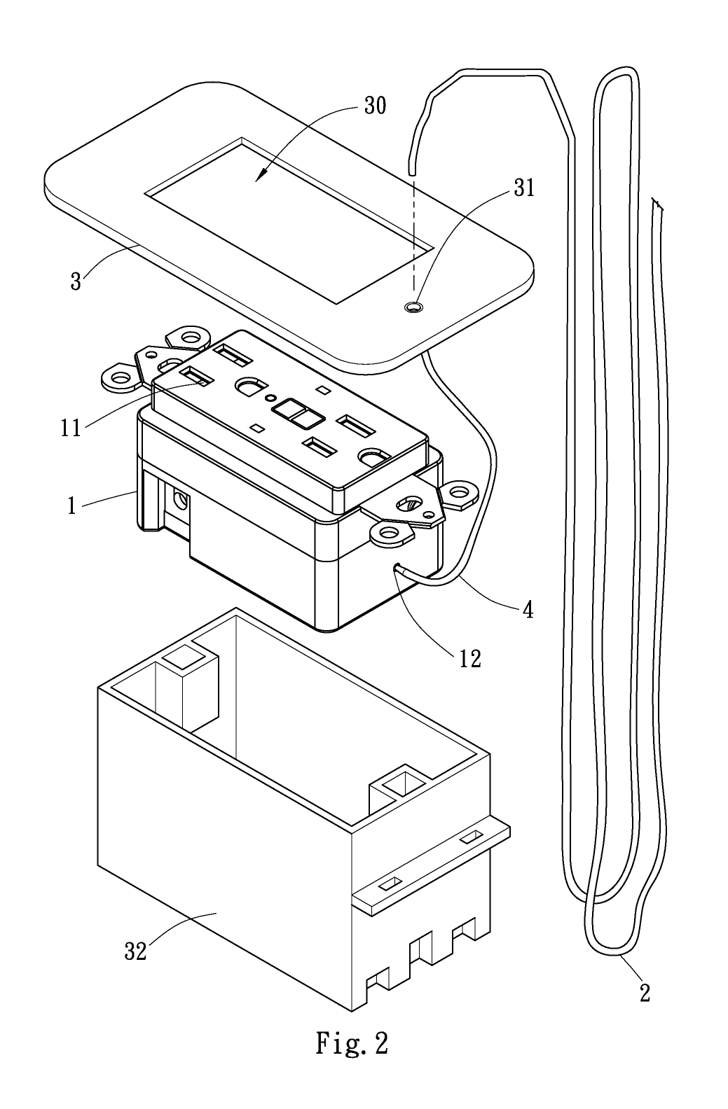

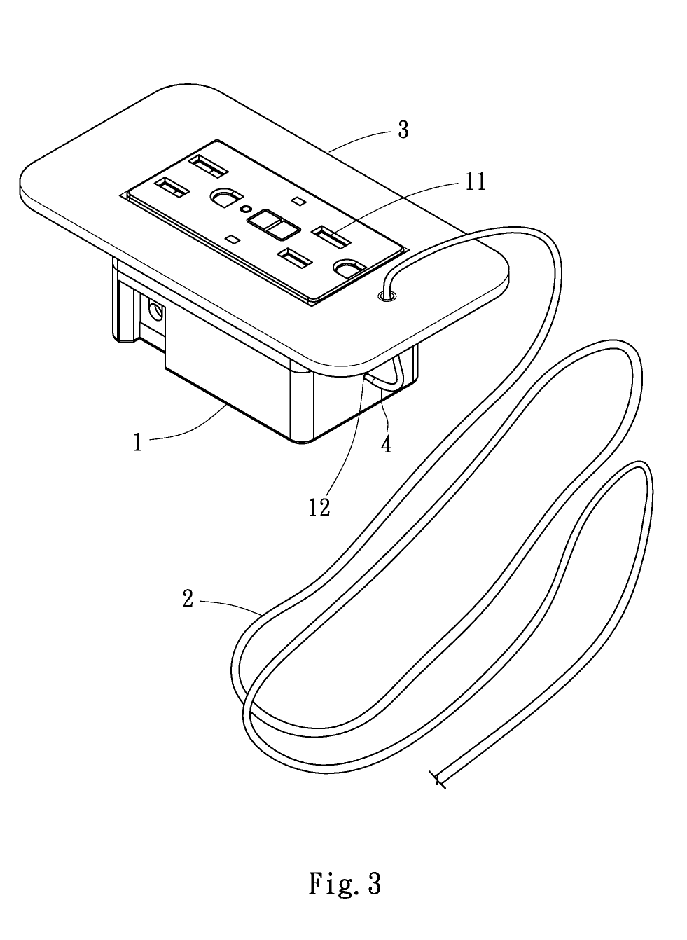

With reference to FIGS. 2 to 4, a wireless intelligent socket assembly with enhanced communication in accordance with the present invention has a wireless intelligent socket 1, a cover 3, a socket holder 32, at least one connection wire 4 and at least one extended antenna 2.

The wireless intelligent socket 1 has multiple sets of plug holes 11, a control circuit and at least one contact hole 12. The multiple sets of plug holes 11 are formed through a top of the wireless intelligent socket 1. The control circuit is mounted inside the wireless intelligent socket 1 to detect a consumed power, such as voltage and current of the power, of each set of plug holes 11 and wirelessly transmit information of the consumed power by a wireless Internet service or Bluetooth transmission. The at least one contact hole 12 is mounted through one side of the wireless intelligent socket 1 and is electrically connected to the control circuit inside the wireless intelligent socket 1.

The cover 3 has an opening 30 and at least one through hole 31. The opening 30 is formed through the cover 3 and is mounted on the top of the wireless intelligent socket 1 with the multiple sets of plug holes 11 exposed through the opening 30. The at least one through hole 31 is formed through the cover 3. The socket holder 32 is correspondingly mounted on a bottom of the cover 3 for the wireless intelligent socket 1 to be mounted in the socket holder 32.

One end of each one of the at least one connection wire 4 is electrically connected to a corresponding contact hole 12, and the other end is electrically connected to an inner end of a corresponding through hole 31 of the cover 3.

One end of each one of the at least one extended antenna 2 is electrically connected to an outer end of a corresponding through hole 31, and the other end extends to a location outside the wireless intelligent socket 1, which is not blocked by any foreign object.

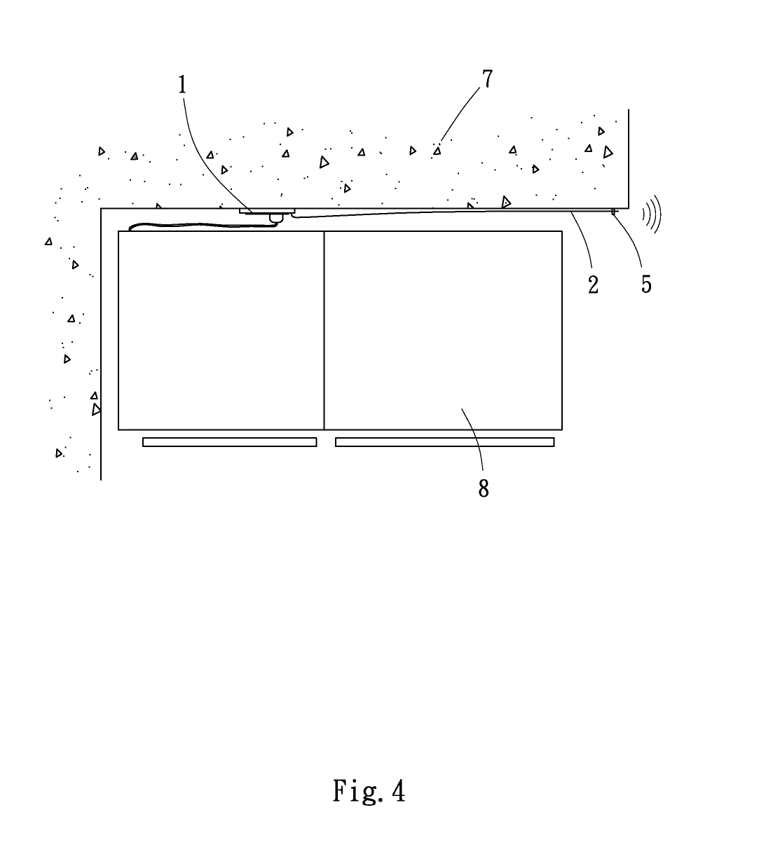

With reference to FIG. 4, when the wireless intelligent socket assembly is operated, the wireless intelligent socket 1 is mounted on a wall 7 with one connection wire 4, one extended antenna 2, one through hole 31, the multiple sets of plug holes 11 of the wireless intelligent socket 1 protruding beyond the wall 7. The connection wire 4 may be located inside the cover 3. One end of the extended antenna 2 is electrically connected to the outer end of the through hole 31 and is thus electrically connected to the connection wire 4, and the other end (free end) of the extended antenna 2 extends outwards along the wall 7 or an object and beyond an electric appliance 8 located in front of and blocking the wireless intelligent socket assembly. When the wireless intelligent socket 1 is operated, the control circuit serves to detect the power consumption of each set of plug holes 11, such as voltage and current of the power, and information of the detected power consumption is sequentially transmitted out through the connection wire 4 and the extended antenna 2, thereby preventing the transmitted information of the detected power consumption from being blocked by any kind of blocks or the electric appliance 8 and further enhancing the communication performance of the detected information of the consumed power transmitted through the wireless intelligent socket 1.

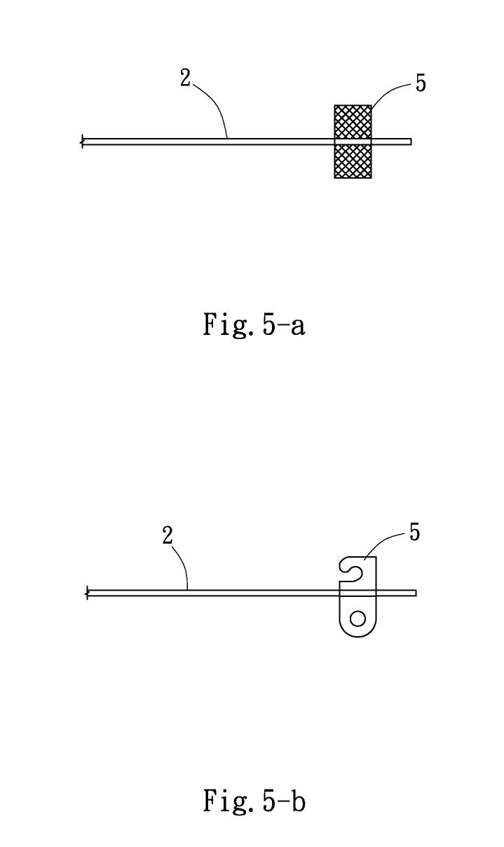

With reference to FIGS. 5a and 5b, the extended antenna 2 has a positioning element 5, such as adhesive tape, a plate with a retaining hole and a hook, mounted on the free end of the extended antenna 2 for the free end to be securely mounted on a desired position of the wall 7 or a surface of other object.

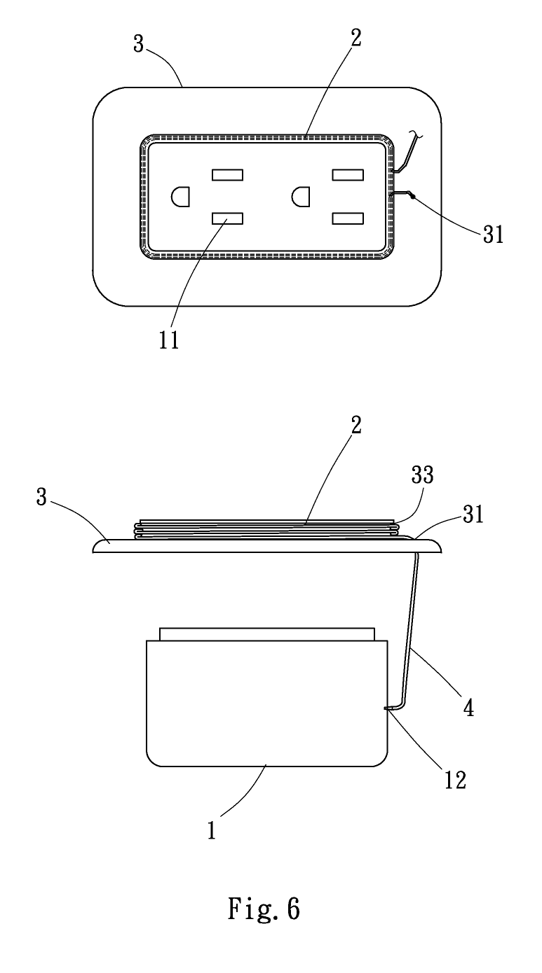

With reference to FIG. 6, a winding portion 33 is helically formed around a perimeter of the opening 30 of the cover 3 in a upward direction so hat the extended antenna 2 can be first wound around the winding portion 33 and the free end of the extended antenna 2 can still extends outwards to an intended position to adjust an extended length of the extended antenna 2 according to a user's requirement.

Even though numerous characteristics and advantages of the present invention have been set forth in the foregoing description, together with details of the structure and function of the invention, the disclosure is illustrative only. Changes may be made in detail, especially in matters of shape, size, and arrangement of parts within the principles of the invention to the full extent indicated by the broad general meaning of the terms in which the appended claims are expressed.

What is claimed is:

1. A wireless intelligent socket assembly comprising:
a wireless intelligent socket having:
multiple sets of plug holes formed through a top of the wireless intelligent socket;
a control circuit mounted inside the wireless intelligent socket to detect a consumed power of each set of plug holes and wirelessly transmit information of the consumed power; and
at least one contact hole mounted through one side of the wireless intelligent socket and electrically connected to the control circuit inside the wireless intelligent socket;
a cover mounted on the top of the wireless intelligent socket and having:
an opening formed through the cover with the multiple sets of plug holes exposed through the opening; and
at least one through hole formed through the cover;
at least one connection wire, wherein one end of each one of the at least one connection wire is electrically connected to a corresponding contact hole, and the other end is electrically connected to an inner end of a corresponding through hole of the cover; and
at least one extended antenna, wherein one end of each one of the at least one extended antenna is electrically connected to an outer end of a corresponding through hole, and the other end is a free end adapted to extend to a location outside the wireless intelligent socket and not blocked by any foreign object.

2. The wireless intelligent socket assembly as claimed in claim 1, wherein the cover has a winding portion helically formed around a perimeter of the opening of the cover in a upward direction for each one of the at least one extended antenna to be wound around the winding portion.

3. The wireless intelligent socket assembly as claimed in claim 1, wherein each one of the at least one extended antenna has a positioning element mounted on the free end of the extended antenna for the free end to be securely mounted on a surface of an object.

4. The wireless intelligent socket assembly as claimed in claim 1, further comprising a socket holder correspondingly mounted on a bottom of the cover for the wireless intelligent socket to be mounted in the socket holder.
